(19) United States
(12) Patent Application Publication
(10) Pub. No.: US 2024/0094646 A1
(43) Pub. Date: Mar. 21, 2024

(54) EXPOSURE APPARATUS AND DECONTAMINATION APPARATUS

(71) Applicant: SAMSUNG ELECTRONICS CO., LTD., Suwon-si (KR)

(72) Inventors: Katsunobu NISHIHARA, Yokohama (JP); Nozomi TANAKA, Yokohama (JP); Tomoyuki JOHZAKI, Yokohama (JP); Ken OZAWA, Yokohama (JP); Atsushi SUNAHARA, Yokohama (JP); Shinji UEYAMA, Yokohama (JP); Shinsuke FUJIOKA, Yokohama (JP); Yubo WANG, Yokohama (JP)

(73) Assignee: SAMSUNG ELECTRONICS CO., LTD., Suwon-si (KR)

(21) Appl. No.: 18/368,995

(22) Filed: Sep. 15, 2023

(30) Foreign Application Priority Data
Sep. 16, 2022 (JP) 2022-148245
Nov. 7, 2022 (KR) 10-2022-0147385

(51) Int. Cl. G03F 7/00; H05G 2/00

(52) U.S. Cl. CPC G03F 7/70925; G03F 7/70033; G03F 7/70175; H05G 2/006

(57) ABSTRACT

An exposure apparatus includes a droplet supplier to supply a target droplet inside a vacuum chamber, an irradiator irradiating a pulsed laser onto the target droplet, a condensing mirror installed inside the vacuum chamber and configured to condense a light emitted from the target droplet by irradiation of the pulsed laser onto the target droplet, a gas supplier to flow a hydrogen gas along a surface of the condensing mirror, a controller to change a supply condition of the target droplet and an irradiation condition of the pulsed laser to conditions different from conditions during an exposure operation to increase an amount of production of hydrogen radicals in the vacuum chamber, and an exhaust pump to exhaust a gas from an inside of the vacuum chamber.

### CROSS-REFERENCE TO RELATED APPLICATION

This application is based on and claims priority under 35 U.S.C. § 119 to Japanese Patent Application No. 2022-148245 filed on Sep. 16, 2022 and Korean Patent Application No. 10-2022-0147385 filed on Nov. 7, 2022, the disclosures of which are incorporated herein by reference in their entireties.

### BACKGROUND

The disclosure relates to an exposure apparatus and a decontamination apparatus, for example, an exposure apparatus using a vacuum ultraviolet ray and an extreme ultraviolet (EUV) optical component decontamination apparatus using a vacuum ultraviolet ray.

Lithography is technology of transferring patterns by a light, which is photographic development technology, when forming a wiring pattern in a semiconductor manufacturing process. Lithography is used for, for example, manufacturing semiconductor chips such as various memory devices, processors, etc.

Recently, exposure apparatuses using an EUV light have been developed to be used for formation of fine patterns of large scale integration (LSI) chips called 7 nm nodes. The wavelength in an ArF or ArF liquid immersion laser is 193 nm. The wavelength of the EUV light is 13.5 nm, which is shorter and has a smaller diffraction limit compared to the exposure apparatus of the prior art.

In EUV lithography technology, to maximize reflectivity of an optical system, a narrowband light of 13.5 nm±2% bw is used. The object material is tin (Sn).

Here, when a driving laser ablates a tin droplet target, fragments of tin, such as atoms, ions, neutral particles, and clusters, are also emitted from a source and accumulated on the surface of a first collector mirror. In addition, the mirror may be damaged or a contaminated tin layer may be formed thereon, thereby reducing reflectivity.

### SUMMARY

The disclosure provides an exposure apparatus and a decontamination apparatus, both capable of effectively removing a tin compound from a contaminated mirror.

In addition, the disclosure is not limited to the above description, and other features may be clearly understood by those of ordinary skill in the art from the descriptions below.

In accordance with an aspect of the disclosure, an exposure apparatus includes a droplet supplier configured to supply a target droplet inside a vacuum chamber; an irradiator configured to irradiate a pulsed laser onto the target droplet; a condensing mirror inside the vacuum chamber, the condensing mirror being configured to condense a light emitted from the target droplet by irradiation of the pulsed laser onto the target droplet; a gas supplier configured to flow a hydrogen gas along a surface of the condensing mirror; a controller configured to change a supply condition of the target droplet and an irradiation condition of the pulsed laser to conditions that are different from conditions during an exposure operation to increase an amount of production of hydrogen radicals in the vacuum chamber; and an exhaust pump configured to exhaust a gas from an inside of the vacuum chamber.

In accordance with an aspect of the disclosure, an exposure apparatus includes a droplet supplier configured to supply a target droplet inside a vacuum chamber; an irradiator configured to irradiate a pulsed laser onto the target droplet; a condensing mirror inside the vacuum chamber, the condensing mirror being configured to condense a light emitted from the target droplet by irradiation of the pulsed laser onto the target droplet; a gas supplier configured to flow a hydrogen gas along a surface of the condensing mirror; a controller configured to change a supply condition of the target droplet and an irradiation condition of the pulsed laser to conditions different from conditions during an exposure operation to increase an amount of production of hydrogen radicals in the vacuum chamber; and an exhaust pump configured to exhaust a gas from an inside of the vacuum chamber, wherein the irradiator includes an extreme ultraviolet (EUV) generating laser unit configured to emit an EUV generating laser; and a vacuum ultraviolet (VUV) generating laser unit configured to emit a VUV generating laser, and wherein the controller is configured to cause the EUV generating laser unit to irradiate a pulsed EUV generating laser onto the target droplet during exposure, and to cause the VUV generating laser unit to irradiate a pulsed VUV generating laser onto the target droplet during cleaning.

In accordance with an aspect of the disclosure, a decontamination apparatus includes a vacuum chamber; a driving laser unit configured to irradiate a driving laser; a light source target configured to supply any one or a mixture of xenon, argon, and nitrogen to a location in which the driving laser is condensed; a vacuum ultraviolet (VUV) condensing lens configured to condense a laser emitted from the light source target; a cleaning cell accommodating an object for cleaning; a hydrogen gas supplier configured to supply a hydrogen gas to the cleaning cell; and an exhaust pump configured to exhaust a gas from an inside of the cleaning cell, wherein the driving laser is irradiated from the driving laser unit onto the light source target to emit the driving laser from the light source target, and the driving laser irradiated onto the hydrogen gas in the cleaning cell increases hydrogen radicals in the cleaning cell to remove a tin compound attached on a surface of the object for cleaning.

### BRIEF DESCRIPTION OF DRAWINGS

Embodiments will be more clearly understood from the following detailed description taken in conjunction with the accompanying drawings in which:

FIG. 1 is a schematic view of a structure of an exposure apparatus, according to an embodiment;

FIGS. 2A and 2B illustrate an operation of an exposure apparatus, according to an embodiment; and

FIG. 3 is a schematic view of a structure of a decontamination apparatus, according to an embodiment.

### DETAILED DESCRIPTION OF EMBODIMENTS

Hereinafter, embodiments of the disclosure are described in detail with reference to the accompanying drawings. Like reference numerals in the drawings denote like elements, and repetitive descriptions are omitted. The embodiments described herein are example embodiments, and thus and thus, the disclosure is not limited thereto and may be realized in various other forms.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

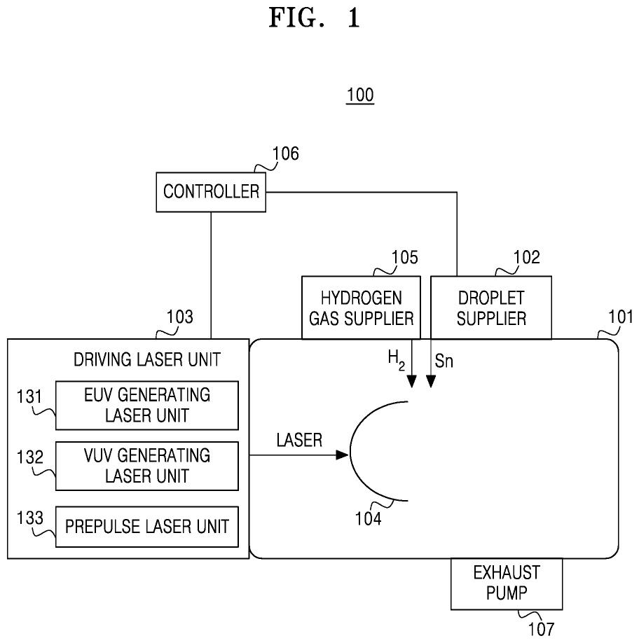

FIG. 1 is a schematic view of a structure of an exposure apparatus, according to an embodiment.

Referring to FIG. 1, an exposure apparatus 100 may include a vacuum chamber 101, a droplet supplier 102, a driving laser unit 103 (e.g., a laser or an irradiator), a condensing mirror 104, a hydrogen gas supplier 105, a controller 106, and an exhaust pump 107.

The vacuum chamber 101 may be a container to make the inside of the vacuum chamber 101 vacuum. A condensing mirror 104 may be disposed inside the vacuum chamber 101. In addition, the vacuum chamber 101 may include one or more ports through which the droplet supplier 102, the driving laser unit 103, the hydrogen gas supplier 105, the controller 106, and the exhaust pump 107 may access the inside of the vacuum chamber 101.

The droplet supplier 102 may supply a target droplet inside the vacuum chamber 101. In particular, the droplet supplier 102 may supply the target droplet such that the target droplet reaches a laser emitted from the driving laser unit 103. Herein, the term “laser” may represent one of a laser beam, a laser light, a laser ray, etc. that is emitted from a laser device such as the driving laser unit 103. The droplet supplier 102 may supply a droplet. In this embodiment, the droplet supplier 102 may include a syringe that ejects the droplet. The syringe may be provided with a needle having a required length and may be configured to eject the droplet from a distal end of the needle.

The driving laser unit 103 may include a component that may irradiate a pulsed laser onto the target droplet. In particular, the driving laser unit 103 may include an EUV generating laser unit 131, a vacuum ultraviolet (VUV) generating laser unit 132, and a prepulse laser unit 133. The EUV generating laser unit 131 may irradiate an infrared wavelength laser and a near-infrared wavelength laser. For example, the EUV generating laser unit 131 may include a CO₂ laser. The VUV generating laser unit 132 may irradiate a near-infrared wavelength laser, a visible light wavelength laser, and an ultraviolet ray wavelength laser. For example, the VUV generating laser unit 131 may include a Nd:YAG laser. In addition, the prepulse laser unit 133 may irradiate a prepulse laser on the target droplet during exposure (e.g., during an exposure operation). For example, the prepulse laser unit 133 may include a Nd:YAG laser.

The condensing mirror 104 may be arranged inside the vacuum chamber 101. In addition, the condensing mirror 104 may condense a light emitted from the target droplet by the irradiation of the laser on the target droplet.

The hydrogen gas supplier 105 may supply a hydrogen gas to the vacuum chamber 101 and flow the hydrogen gas along the surface of the condensing mirror 104. The hydrogen gas supplier 105 may supply a process gas into the vacuum chamber 101. For example, the hydrogen gas may be supplied from the hydrogen gas supplier 105 to the gas supply pipe through a flow controller and a valve. The flow rate controller may adjust the supply flow rate of the hydrogen gas. The valve may control the flow rate of the hydrogen gas in an on/off manner. For example, a valve can be formed between a flow controller (not shown) and a gas supply pipe to control the supply of the hydrogen gas flowing to the gas supply pipe.

The controller 106 may control the droplet supplier 102 and the driving laser unit 103. In addition, the controller 106 may change the supply condition of the target droplet and the irradiation condition of the laser to conditions different from the exposure conditions to increase the amount of production of hydrogen radicals in the vacuum chamber 101.

For example, the controller 106 may control the EUV generating laser unit 131 to irradiate a pulsed EUV generating laser on the target droplet during exposure. In addition, the controller 106 may control the VUV generating laser unit 132 to irradiate a pulsed vacuum ultraviolet ray laser on the target droplet during cleaning (e.g., a cleaning operation).

In addition, for example, the controller 106 may control the intensity of emission of the laser during the cleaning to be less than that of the laser during the exposure.

In addition, the controller 106 may control the density of the target droplet supplied during the cleaning to be greater than that of the target droplet supplied during the exposure.

The controller 106 may control the prepulse laser unit 133 to irradiate the prepulse laser onto the target droplet in advance during the exposure. In addition, the controller 106 may control the prepulse laser unit 133 not to emit the prepulse laser during cleaning.

In addition, the controller 106 may control the size of the target droplet supplied during the cleaning to be greater than that of the target droplet supplied during the exposure.

The exhaust pump 107 may be a pump for exhausting a gas from the inside of the vacuum chamber 101.

Next, a condition of increasing the amount of production of hydrogen radicals is described.

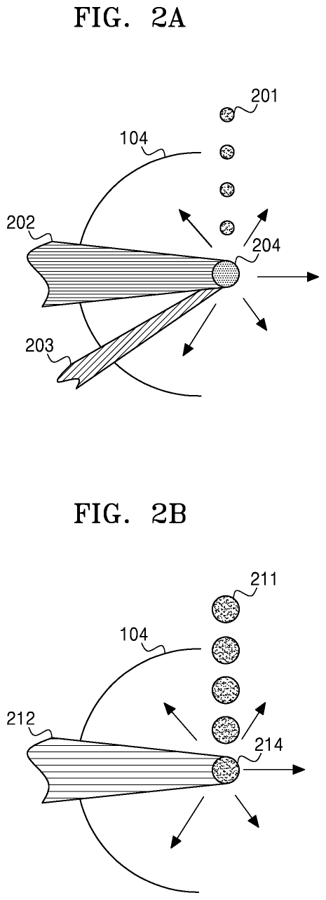

FIGS. 2A and 2B illustrate an operation of the exposure apparatus, according to an embodiment. Referring to FIG. 2, an example of changing the wavelength of the laser, the intensity of the laser, irradiation in advance, and the density and size of the target droplet during the exposure and the cleaning is described.

FIG. 2A illustrates the state of the exposure apparatus during exposure.

Referring to FIG. 2A, an EUV generating laser 202 may be irradiated onto a target droplet 201 during exposure. In addition, the intensity of the EUV generating laser 202 during exposure is about 10¹⁰ W/cm² to about 10¹¹ W/cm². In addition, a laser 203 (e.g., a prepulse laser irradiated by the prepulse laser unit 133) may be irradiated onto the target droplet 201 by irradiation in advance. Through the irradiation in advance, the target droplet 204 may be heated and the density thereof may be reduced. In addition, the size of the supplied target droplet 201 may be small.

FIG. 2B illustrates the state of the exposure apparatus during cleaning.

Referring to FIG. 2B, a VUV generating laser 212 may be irradiated onto a target droplet 211 during cleaning. In addition, the intensity of the VUV generating laser 212 during cleaning may be less than 10⁹ W/cm². In addition, irradiation in advance (e.g., by the prepulse laser unit 133) may not occur during cleaning. Therefore, the density of the target droplet 214 during cleaning may be greater than the density of the target droplet 204 during exposure. In addition, the size of the target droplet 214 supplied during cleaning may be greater than the size of the target droplet 204 supplied during exposure.

According to the exposure apparatus of the present embodiment, the supply condition of the target droplet and the irradiation condition of the laser during cleaning may be changed to conditions different from the exposure conditions to increase the amount of production of hydrogen radicals in the vacuum chamber, thereby causing tin attached on the mirror to react with the hydrogen radicals to become SnH₄ and thus be removed from the mirror.

In addition, according to the exposure apparatus of the present embodiment, the controller may control the EUV generating laser unit to irradiate the pulsed EUV generating laser onto the target droplet during the exposure, and control the VUV laser unit to irradiate the pulsed VUV generating laser onto the target droplet during the cleaning, thereby shortening the wavelength of the laser during cleaning to increase the amount of production of hydrogen radicals and making the tin attached on the mirror react with hydrogen radicals to become SnH₄ and thus be more efficiently removed from the mirror.

In addition, according to the exposure apparatus of the present embodiment, the controller may control the intensity of the laser emitted during cleaning to be less than the intensity of the laser emitted during exposure, thereby increasing the amount of production of hydrogen radicals and making the tin attached on the mirror react with hydrogen radicals to become SnH₄ and thus be more efficiently removed from the mirror.

In addition, according to the exposure apparatus of the present embodiment, the density of the target droplet supplied during cleaning may be made greater than the density of the target droplet supplied during exposure, thereby increasing the amount of production of hydrogen radicals and making the tin attached on the mirror react with hydrogen radicals to become SnH₄ and thus be more efficiently removed from the mirror.

In addition, according to the exposure apparatus of the present embodiment, by not emitting the laser from the prepulse laser unit during cleaning, the density of the target droplet supplied during cleaning may be made greater than the density of the target droplet supplied during exposure.

In addition, according to the exposure apparatus of the present embodiment, the controller may control the size of the target droplet supplied during cleaning to be greater than the size of the target droplet supplied during exposure, thereby increasing the amount of production of hydrogen radicals and making the tin attached on the mirror react with hydrogen radicals to become SnH₄ and thus be more efficiently removed from the mirror.

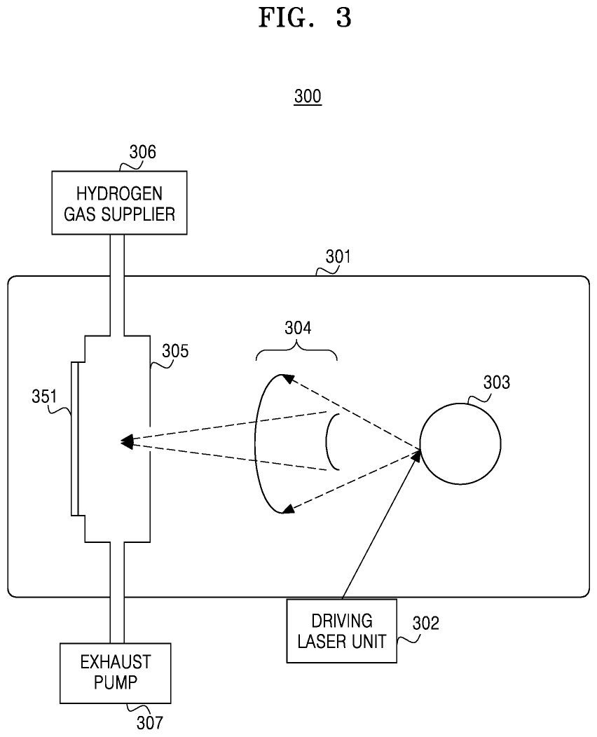

FIG. 3 is a schematic view of a structure of a decontamination apparatus, according to an embodiment.

Referring to FIG. 3, a decontamination apparatus 300 may include a vacuum chamber 301, a driving laser unit 302, a light source target 303, a VUV condensing mirror 304, a cleaning cell 305, a hydrogen gas supplier 306, and an exhaust pump 307.

The vacuum chamber 301 may be a container to make the inside of the vacuum chamber 301 vacuum. The vacuum chamber 301 may include a condensing mirror 304, a light source target 303, and a cleaning cell 305 inside thereof. In addition, the vacuum chamber 301 may include one or more ports through which the hydrogen gas supplier 306, the exhaust pump 307, and a driving laser may access the inside of the vacuum chamber 301.

The driving laser unit 302 may irradiate a driving laser. Here, the driving laser unit 302 may irradiate the driving laser onto the light source target 303.

The light source target 303 may continuously supply any one of an inert gas, such as xenon, argon, and nitrogen, or a mixture thereof, to a condensing point of the driving laser.

The VUV condensing mirror 304 may condense plasma radiation irradiated from the light source target 303. The condensed plasma radiation may be irradiated onto the inside of the cleaning cell 305.

The cleaning cell 305 may accommodate an object for cleaning. In addition, the cleaning cell 305 may include an opening for irradiating (e.g., transmitting) the plasma radiation emitted from the light source target 303 onto the inside of the cleaning cell 305. In addition, the cleaning cell 305 may include an insertion port 351 into which an object for cleaning is inserted for delivering the object for cleaning.

The hydrogen gas supplier 306 may supply a hydrogen gas to the cleaning cell 305.

The exhaust pump 307 may exhaust a gas from the inside of the cleaning cell 305.

Because the decontamination apparatus 300 irradiates the driving laser from the driving laser unit 302 to the light source target 303, a VUV light may be irradiated from the surface of the light source target 303. In addition, the decontamination apparatus 300 may produce hydrogen radicals in the cleaning cell 305 by irradiating a VUV light onto the hydrogen gas in the cleaning cell 305. In addition, the decontamination apparatus 300 may remove a tin compound attached on the surface of the object for cleaning.

In this regard, according to the decontamination apparatus of the present embodiment, by irradiating the VUV light onto the hydrogen gas in the cleaning cell 305, hydrogen radicals are produced in the cleaning cell and react with the tin compound to become SnH₄, and then are exhausted through the exhaust pump 307, thereby removing the tin compound attached on the surface of the object for cleaning.

In addition, the disclosure is not limited to the above embodiments and may be changed accordingly without deviating from a range of the disclosure. For example, the exposure apparatus of the previous embodiment may have a general configuration of a semiconductor exposure apparatus.

In addition, a functional block that performs various processes as illustrated in the drawings, such as the controller 106, may be implemented as hardware, such as a central processing unit (CPU), a memory, and other circuits, and as software, such as a program loaded on a memory, etc. Therefore, it would be understood by those of ordinary skill in the art that such a functional block may be implemented in various forms such as hardware, a software, or a combination thereof.

The program described above may be contained in various types of non-transitory computer-readable media and provided to a computer. The non-transitory computer-readable media may include various types of physical recording media. Examples of the non-transitory computer-readable medium may include a magnetic recording medium (e.g., flexible disks, magnetic tapes, hard disk drives), a magnet optical recording medium (e.g., optical magnetic disks), a compact disc read only memory (CD-ROM), a CD recordable (CD-R) disc, a CD rewritable (CD-R/W) disc, a semiconductor memory (e.g., mask ROM, programmable ROM (PROM), erasable PROM (EPROM), flash ROM, and random access memory (RAM)). In addition, the program may be provided to the computer by various types of transitory computer-readable media. Examples of the transitory computer-readable medium may include electric signals, optical signals, and electromagnetic waves. The transitory computer-readable medium may supply a program to the computer with wired communication routes such as wires and optical fibers or a wireless communication route in between.

While the disclosure has been particularly shown and described with reference to embodiments thereof, it will be understood that various changes in form and details may be made therein without departing from the spirit and scope of the following claims.

What is claimed is:

1. An exposure apparatus comprising:
a droplet supplier configured to supply a target droplet inside a vacuum chamber;
an irradiator configured to irradiate a pulsed laser onto the target droplet;
a condensing mirror in the vacuum chamber, the condensing mirror being configured to condense a light emitted from the target droplet by irradiation of the pulsed laser onto the target droplet;
a gas supplier configured to flow a hydrogen gas along a surface of the condensing mirror;
a controller configured to change a supply condition of the target droplet and an irradiation condition of the pulsed laser to conditions that are different from conditions during an exposure operation to increase an amount of production of hydrogen radicals in the vacuum chamber; and
an exhaust pump configured to exhaust a gas from an inside of the vacuum chamber.

2. The exposure apparatus of claim 1, wherein the irradiator comprises an extreme ultraviolet (EUV) generating laser unit configured to irradiate an EUV generating laser, and a vacuum ultraviolet (VUV) generating laser unit configured to irradiate a VUV generating laser,
wherein the controller is configured to cause the EUV generating laser unit to irradiate a pulsed EUV generating laser onto the target droplet during the exposure operation, and
wherein the controller is configured to cause the VUV generating laser unit to irradiate a pulsed VUV generating laser onto the target droplet during a cleaning operation.

3. The exposure apparatus of claim 1, wherein the controller is configured to control an intensity of the pulsed laser emitted during a cleaning operation to be less than an intensity of the pulsed laser emitted during the exposure operation.

4. The exposure apparatus of claim 1, wherein the controller is configured to control a density of the target droplet supplied during a cleaning operation to be greater than a density of the target droplet supplied during the exposure operation.

5. The exposure apparatus of claim 4, wherein the irradiator comprises a prepulse laser unit configured to irradiate a prepulse laser onto the target droplet in advance of the pulsed laser during the exposure operation,
wherein the controller is configured to cause the prepulse laser unit to irradiate the prepulse laser onto the target droplet in advance of the pulsed laser during the exposure operation, and
wherein the controller is configured to cause the prepulse laser unit to refrain from irradiating the prepulse laser during the cleaning operation.

6. The exposure apparatus of claim 1, wherein the controller is configured to control a size of the target droplet supplied during a cleaning operation to be greater than a size of the target droplet supplied during the exposure operation.

7. The exposure apparatus of claim 1, wherein the vacuum chamber comprises a port through which an inside of the vacuum chamber is accessible by the droplet supplier, the irradiator, the gas supplier, the controller, and the exhaust pump.

8. The exposure apparatus of claim 2, wherein the EUV generating laser unit is configured to irradiate one of infrared and near-infrared wavelength lasers onto the target droplet.

9. The exposure apparatus of claim 2, wherein the VUV generating laser unit is configured to irradiate at least one of an infrared wavelength laser, a visible light wavelength laser, and an ultraviolet ray wavelength laser onto the target droplet.

10. The exposure apparatus of claim 2, wherein the EUV generating laser unit is configured to irradiate the EUV generating laser at an intensity of about 10¹⁰ W/cm 2 to about 10¹¹ W/cm².

11. The exposure apparatus of claim 2, wherein the VUV generating laser unit is configured to irradiate the VUV generating laser at an intensity less than about 10⁹ W/cm 2.

12. The exposure apparatus of claim 1, wherein the controller is configured to change the supply condition of the target droplet and the irradiation condition of the pulsed laser to conditions different from the conditions during the exposure operation to remove a tin attached on a mirror from the mirror.

13. The exposure apparatus of claim 1, wherein the controller is configured to control a wavelength of the pulsed laser emitted during a cleaning operation to be less than a wavelength of the pulsed laser emitted during the exposure operation.

14. An exposure apparatus comprising:
a droplet supplier configured to supply a target droplet inside a vacuum chamber;
an irradiator configured to irradiate a pulsed laser onto the target droplet;
a condensing mirror inside the vacuum chamber, the condensing mirror being configured to condense a light emitted from the target droplet by irradiation of the pulsed laser onto the target droplet;
a gas supplier configured to flow a hydrogen gas along a surface of the condensing mirror;
a controller configured to change a supply condition of the target droplet and an irradiation condition of the pulsed laser to conditions different from conditions during an exposure operation to increase an amount of production of hydrogen radicals in the vacuum chamber; and
an exhaust pump configured to exhaust a gas from an inside of the vacuum chamber,
wherein the irradiator comprises:
an extreme ultraviolet (EUV) generating laser unit configured to emit an EUV generating laser; and
a vacuum ultraviolet (VUV) generating laser unit configured to emit a VUV generating laser, and
wherein the controller is configured to cause the EUV generating laser unit to irradiate a pulsed EUV generating laser onto the target droplet during exposure, and to cause the VUV generating laser unit to irradiate a pulsed VUV generating laser onto the target droplet during cleaning.

15. The exposure apparatus of claim 14, wherein the EUV generating laser unit is configured to irradiate one of infrared and near-infrared wavelength lasers onto the target droplet, and
wherein the VUV generating laser unit is configured to irradiate at least one of an infrared wavelength laser, a visible light wavelength laser, and an ultraviolet ray wavelength laser onto the target droplet.

16. The exposure apparatus of claim 14, wherein the irradiator comprises a prepulse laser unit configured to irradiate a prepulse laser onto the target droplet in advance of the pulsed laser during the exposure operation,
wherein the controller is configured to cause the prepulse laser unit to irradiate the prepulse laser onto the target droplet in advance of the pulsed laser during the exposure operation, and
wherein the controller is configured to cause the prepulse laser unit to refrain from irradiating the prepulse laser during a cleaning operation.

17. The exposure apparatus of claim 14, wherein the controller is configured to change the supply condition of the target droplet and the irradiation condition of the pulsed laser such that tin attached on the condensing mirror becomes SnH₄.

18. An exposure apparatus comprising:
a vacuum chamber;
a driving laser unit configured to irradiate a driving laser;
a light source target configured to supply any one or a mixture of xenon, argon, and nitrogen to a location in which the driving laser is condensed;
a vacuum ultraviolet (VUV) condensing lens configured to condense a laser emitted from the light source target;
a cleaning cell accommodating an object for cleaning;
a hydrogen gas supplier configured to supply a hydrogen gas to the cleaning cell; and
an exhaust pump configured to exhaust a gas from an inside of the cleaning cell,
wherein the driving laser is irradiated from the driving laser unit onto the light source target to emit the driving laser from the light source target, and
wherein the driving laser irradiated onto the hydrogen gas in the cleaning cell increases hydrogen radicals in the cleaning cell to remove a tin compound attached on a surface of the object for cleaning.

19. The exposure apparatus of claim 18, wherein the cleaning cell further comprises an opening transmitting plasma radiation emitted from the light source target onto an inside of the cleaning cell.

20. The exposure apparatus of claim 18, wherein the cleaning cell further comprises an insertion port into which the object for cleaning is inserted to deliver the object for cleaning.
